(19) United States
(12) Patent Application Publication
(10) Pub. No.: US 2012/0293922 A1
(43) Pub. Date: Nov. 22, 2012

(54) MOVABLE MEDICAL MONITOR WITH BATTERY PACKS

(75) Inventor: Kenzo SUDO, San Jose, CA (US)

(73) Assignee: ADVAN Int'l Corp., Fremont, CA (US)

(21) Appl. No.: 13/109,278

(22) Filed: May 17, 2011

(51) Int. Cl. H05K 7/00

(52) U.S. Cl. 361/679.01

(57) ABSTRACT

Disclosed herein is a movable medical monitor that is capable of being operated without connection to an external power supply and is freely movable. The movable medical monitor includes a stand including a cylindrical rod and a base detachably coupled to a lower end of the cylindrical rod and having a plurality of movable wheels; a power station seated on an upper side of the base by fitting a semi-circular groove formed at one side of a body into the circular rod, the power station including a plurality of slots each being combined with a battery; a battery pack coupled to the slot; and a monitor coupled to an upper portion of the cylindrical rod and electrically connected to the power station to receive power.

### BACKGROUND

1. Technical Field

Embodiments of the invention relate to a medical monitor and, more particularly, to a movable medical monitor that is capable of operating without connection to an external power supply and is thus freely movable when mounted on a stand with wheels.

2. Description of the Related Art

Since the field of medicine is a very important and unique area dealing with human life, medicine is at the leading edge of technology where various fields are tested and applied. A variety of techniques are employed in the field of medicine such as chemical and biological techniques to develop new substances and materials, mechanical techniques to develop medical equipment, surgical robots or capsulated micro-robots, electric and electronic techniques to develop various types of diagnostic and test equipment, IT techniques to lead ubiquitous medical care environments, and the like.

For example, in electric and electronic applications closely related to various types of diagnostic and test equipment, a display device for displaying diagnosis results of a patient with a disease using image information is widely used. As such a display device, a liquid crystal display (LCD), which is thin and light, is generally used.

Medical display devices are adopted in consideration of use environments. Since medical treatment frequently requires cooperation between doctors or nurses, moving quickly within a relatively limited space, it is important to efficiently arrange a variety of medical devices in the space. In particular, since it is necessary to accurately read image information regarding patient conditions displayed on a medical monitor, the medical monitor is positioned near medical workers.

Such arrangement of the medical monitor frequently hinders movement of medical workers and causes persons to trip and fall over data cables or other cables connected to the medical monitor, or the monitor to fall and be damaged due to the cables. Moreover, accidents by interference between the medical workers and the monitor may not only cause damage to the monitor or injury to the medical workers but also affect the health and life of patients receiving medical treatment.

Further, mobility of the medical monitor connected to an external power supply is limited. If a place does not provide an external power supply or an outlet of an external power supply is distant from a place at which the monitor is to be disposed, serious inconvenience is caused in performance of medical procedures.

However, since no freely movable specialized medical monitors are available, there is an urgent need for development of such monitors.

### BRIEF SUMMARY

One aspect of the present invention is to provide a medical monitor which uses a rechargeable power supply, instead of an external power supply, to drive the monitor, thereby optimizing use of the monitor.

Another aspect of the present invention is to provide a medical monitor having maximally improved mobility by integrating a rechargeable power supply and the monitor into a wheeled stand.

Still another aspect of the present invention is to provide a medical monitor which does not require wire connection of a cable for receiving image information from an external imaging device, thereby providing optimized mobility for medical environments frequently requiring quick movement of the monitor.

In accordance with one aspect of the invention, a movable medical monitor includes a stand including a cylindrical rod and a base detachably coupled to a lower end of the cylindrical rod and having a plurality of movable wheels; a power station seated on an upper side of the base by fitting a semi-circular groove formed at one side of a body into the circular rod, the power station including a plurality of slots each being combined with a battery; a battery pack coupled to the slot; and a monitor coupled to an upper portion of the cylindrical rod and electrically connected to the power station to receive power.

The power station may include a detachable power cord, and the battery pack inserted into the slot may be charged when the power cord is connected to an external power supply.

The power station may include a power cord automatically wound by restoring force of an elastic member provided therein, and the battery pack inserted into the slot may be charged when the power cord is connected to an external power supply.

The monitor and the power station may be electrically connected to each other through a space defined in the cylindrical rod.

The plurality of slots may be disposed inside of the power station protected by a cover which can be opened and closed.

The plurality of slots may include two slots respectively provided at right and left sides of the power station, and the power station may include two indicator lights disposed on an upper side thereof. The two indicator lights display charging amounts of two battery packs, respectively.

The monitor may be a wireless monitor which receives image information from an external imaging device wirelessly.

The power station may provide power to the monitor when at least one battery pack is coupled to the slots.

The base may have a stepped shape where a peripheral region of the base having the movable wheels is higher than a central region of the base coupled to the cylindrical rod, and a center of gravity of the power station combined with the battery pack may be positioned towards the movable wheels rather than the cylindrical rod.

### BRIEF DESCRIPTION OF THE DRAWINGS

The above and other aspects, features, and advantages of the invention will become apparent from the detailed description of the following embodiments in conjunction with the accompanying drawings:

FIG. 1 is a perspective view of a movable medical monitor according to an exemplary embodiment of the present invention; and

FIG. 2 is a disassembled perspective view illustrating the internal configuration of a power station of the movable medical monitor shown in FIG. 1.

### DETAILED DESCRIPTION

An exemplary embodiment of the present invention will now be described in detail with reference to the accompanying drawings.

Herein, descriptions of elements apparent to those skilled in the art will be omitted for clarity and conciseness. In the drawings, the size and relative sizes of elements in the drawings may be exaggerated for clarity and ease of description.

Further, relative positional terms such as front, back, right, left, up, down and the like are based on orientations in the drawings. It will be understood that the relative positional terms are intended to encompass different orientations of the device in use or operation, in addition to the orientation depicted in the figures without departing from the teachings of the present invention.

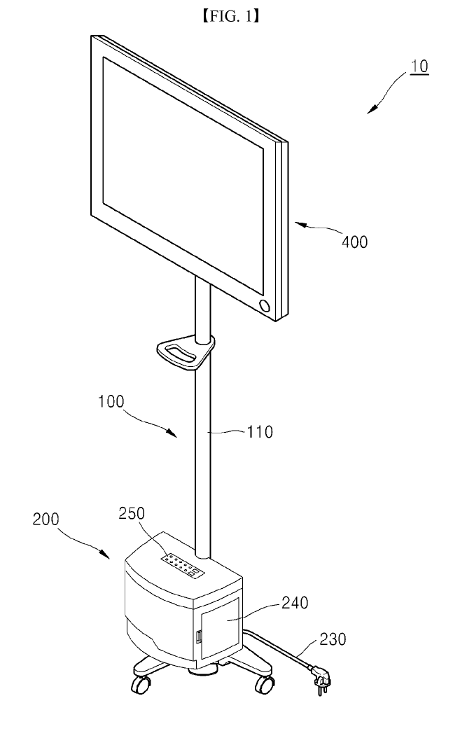

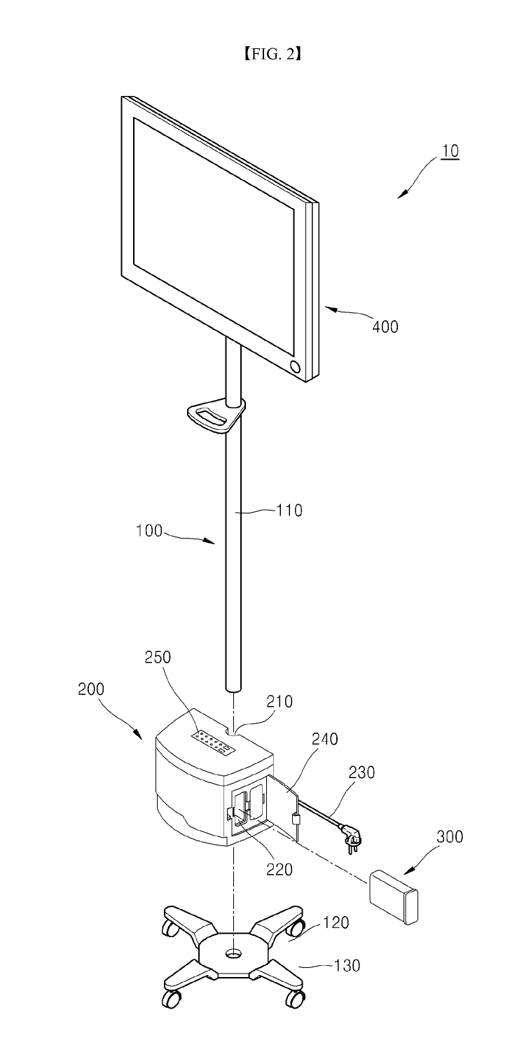

FIG. 1 is a perspective view of the movable medical monitor 10 according to an exemplary embodiment of the present invention, and FIG. 2 is a disassembled perspective view illustrating the internal configuration of a power station of the movable medical monitor 10 shown in FIG. 1.

In FIGS. 1 and 2, the medical monitor 10 according to the embodiment includes a stand 100, a power station 200, battery packs 300, and a monitor 400.

The stand 100 includes a cylindrical rod 110 and a base 120, which is detachably coupled to a lower end of the cylindrical rod 110 and includes a plurality of movable wheels 130. The stand 100 has substantially the same configuration as a movable stand generally used in hospitals, and thus a detailed description thereof will be omitted herein. Here, it should be noted that although the rod vertically coupled to the stand 100 is illustrated as having a cylindrical shape, this configuration is provided for illustrative purpose and the invention is not limited thereto.

The power station 200 is coupled to the circular rod 110 through a semi-circular groove 210 formed at one side of a body of the power station 200, so that the power station is seated on an upper side of the base 120. The body of the power station 200 is provided with a plurality of slots 220 to which the detachable battery packs 300 are electrically connected. The battery pack 300 is coupled to each of the slots 220 is coupled and power charged in each battery pack 300 is integrated and managed by the power station 200.

The monitor 400 is coupled to an upper portion of the cylindrical rod 110 and may be configured as a liquid crystal display (LCD) which is slim and light and consumes little power. The monitor 400 is electrically connected to the power station 200 to receive power and is driven thereby.

The power station 200 may include a detachable power cord 230. When the power cord 230 is connected to an external power supply, the battery pack 300 inserted into the slot 220 may be charged. Alternatively, the power cord 230 may be automatically wound by restoring force of an elastic member (not shown) provided to the power station 200. Obviously, the power station 200 may include an adaptor (not shown) which converts alternating current into direct current, so that the external power supply allows the battery pack 300 to be charged while driving the monitor 400. Such power management is integrally performed by the power station 200.

In particular, in the case where the power cord 230 is automatically wound by the restoring force of the elastic member provided in the power station 200, the power cord 230 is stowed in the body of the power station 200 when not connected to the external power supply. Due to this configuration, unnecessary cables are not arranged around the monitor 400, thereby providing a tidy environment. Further, the monitor 400 and the power station 200 may be electrically connected to each other through a space defined in the cylindrical rod 110 so that no cables are exposed to the outside.

In one exemplary embodiment of the invention, the plurality of slots 220 is disposed in an internal space of the power station 200 protected by a cover 240 which can be opened and closed. Specifically, two slots 220 may be provided at right and left sides of the power station 200, respectively, and the power station 200 provides power to the monitor 400 when at least one battery pack 300 is coupled to the corresponding slot 220. That is, when the battery pack 300 is coupled to at least one of the plural slots 220, power is supplied.

When the base 120 of the stand 100 has a stepped shape where a peripheral region of the base 120 having the movable wheels 130 is higher than a central region thereof coupled to the cylindrical rod 110, as shown in FIGS. 1 and 2, the center of gravity of the power station 200 combined with the battery pack 300 may be designed to be positioned towards the movable wheels 130 rather than the cylindrical rod 110. For example, the slots 220, into which the battery packs 300 having a certain weight are inserted, are disposed closer to the movable wheels 130 so that the center of gravity of the power station 200 may be positioned towards the movable wheels 130. This structure is designed to stably seat the power station on the base 120 of the stand 100.

The power station 200 includes two indicator lights 250 disposed on an upper side thereof to display the charging amounts of two battery packs 300, respectively. The indicator lights 250 provide information about the charging amounts of the battery packs 300, charging conditions of the battery packs 300, and the like. Particularly, the battery packs 300 used in this embodiment may be charged in advance using an external charger.

In this embodiment, the monitor 400 is configured as a wireless monitor that receives image information from an external imaging device wirelessly, such as an endoscope. Thus, the monitor 400 does not include any cable to be connected to the external imaging device. Due to this configuration, the stand 100 to which the monitor 400 is fixed may have maximized mobility, so that the monitor 400 of the embodiment is appropriate for medical environments frequently requiring quick movement of the monitor 400. A various types of wireless monitors can be obtained from the market and detailed descriptions thereof will be omitted herein.

As such, according to the embodiments, a monitor and a rechargeable battery pack are integrated into a wheeled stand so that the monitor may be disposed at a proper position for medical procedure and is freely movable, thereby being appropriate for medical use.

Further, the monitor is a wireless monitor which does not require wire connection of a cable for receiving image information from an external imaging device, thereby having maximized mobility. Thus, the monitor is appropriate for medical environments requiring quick transfer of the monitor.

Although some embodiments have been described herein, it should be understood by those skilled in the art that these embodiments are given by way of illustration only, and that various modifications, variations, and alterations can be made without departing from the spirit and scope of the invention. Therefore, the scope of the invention should be limited only by the accompanying claims and equivalents thereof

What is claimed is:

1. A movable medical monitor comprising:
a stand including a cylindrical rod and a base detachably coupled to a lower end of the cylindrical rod, the base having a plurality of movable wheels;
a power station seated on an upper side of the base by fitting a semi-circular groove formed at one side of a body of the power station into the circular rod, the power station including a plurality of slots each being combined with a battery;
a battery pack coupled to the slot; and
a monitor coupled to an upper portion of the cylindrical rod and electrically connected to the power station to receive power.

2. The movable medical monitor of claim 1, wherein the power station comprises a detachable power cord and the battery pack inserted into the slot is charged when the power cord is connected to an external power supply.

3. The movable medical monitor of claim 1, wherein the power station comprises a power cord automatically wound by restoring force of an elastic member provided therein and the battery pack inserted into the slot is charged when the power cord is connected to an external power supply.

4. The movable medical monitor of claim 1, wherein the monitor and the power station are electrically connected to each other through a space defined in the cylindrical rod.

5. The movable medical monitor of claim 1, wherein the plurality of slots are disposed within the power station protected by a cover which can be opened and closed.

6. The movable medical monitor of claim 5, wherein the plurality of slots comprises two slots respectively provided at right and left sides of the power station.

7. The movable medical monitor of claim 6, wherein the power station comprises two indicator lights disposed on an upper side thereof, the two indicator lights displaying charging amounts of two battery packs, respectively.

8. The movable medical monitor of claim 1, wherein the monitor is a wireless monitor which receives image information from an external imaging device wirelessly.

9. The movable medical monitor of claim 1, wherein the power station provides power to the monitor when at least one battery pack is coupled to the slot.

10. The movable medical monitor of claim 1, wherein the base has a stepped shape where a peripheral region of the base having the movable wheels is higher than a central region of the base coupled to the cylindrical rod, and a center of gravity of the power station combined with the battery pack is positioned towards the movable wheels rather than the cylindrical rod.
